(19) United States
(12) Patent Application Publication
(10) Pub. No.: US 2016/0311127 A1
(43) Pub. Date: Oct. 27, 2016

(54) CUTTING APPARATUS AND CUTTING METHOD

(71) Applicant: DISCO CORPORATION, Tokyo (JP)

(72) Inventors: Yuya Itatani, Tokyo (JP); Yoshiki Ishiai, Tokyo (JP)

(21) Appl. No.: 14/695,704

(22) Filed: Apr. 24, 2015

(51) Int. Cl. B26D 7/08; H01L 21/67; B28D 5/02; H01L 21/78; B26D 7/01; B26D 7/18

(52) U.S. Cl. CPC B26D 7/088; B26D 7/01; B26D 7/18; B28D 5/022; H01L 21/78; H01L 21/67092

(57) ABSTRACT

A cutting apparatus for cutting a workpiece includes: a holding unit for holding the workpiece; a cutting unit including a cutting blade for cutting the workpiece held by the holding unit, and a spindle for rotating the cutting blade; a cutting water supplying unit for supplying cutting water to the cutting blade; and a cleaning fluid jetting unit for jetting to the cutting blade a cleaning fluid for removal of matter adhered to the cutting blade.

### BACKGROUND OF THE INVENTION

1. Field of the Invention

The present invention relates to a cutting apparatus and a cutting method for cutting a workpiece such as a semiconductor wafer.

2. Description of the Related Art

A workpiece such as a semiconductor wafer and a glass substrate is cut by a cutting apparatus having a rotating annular cutting blade, for example, and is thereby divided into a plurality of chips (see, for example, Japanese Patent Laid-open No. 2007-59432). Prior to the cutting of the workpiece, a dicing tape is attached to the back side of the workpiece, and an annular frame surrounding the workpiece is fixed to a peripheral portion of the dicing tape. This makes it possible to prevent scattering of the chips after the cutting and thereby to maintain handleability of the chips. The aforementioned cutting blade is formed by binding abrasive grains of diamond, CBN (cubic boron nitride) or the like with a binder such as a metal or resin. The cutting blade is made to cut into the workpiece from the front side of the workpiece until it reaches the dicing tape on the back side of the workpiece, whereby the workpiece can be cut completely.

### SUMMARY OF THE INVENTION

Meanwhile, the dicing tape attached to the workpiece in the cutting process as aforementioned is formed of a material, such as resin, which is higher in viscosity than the workpiece. When the cutting blade is made to cut into the dicing tape, therefore, the debris (cuttings) generated at the dicing tape are likely to stick to the cutting blade, resulting in clogging. Similarly, when a workpiece formed of a metal, resin or the like having high viscosity or a workpiece having a highly viscous material disposed at predetermined processing lines is cut by use of the aforementioned cutting blade, the debris (cuttings) generated from the workpiece are likely to stick to the cutting blade, thereby clogging the cutting blade. Such a clogging of the cutting blade lowers the cutting performance of the cutting blade. A lowering in the cutting performance of the cutting blade, in turn, is likely to cause the generation of defects such as chippings and burring in the workpiece. In addition, the cutting blade in such a situation is liable to meander under the load during cutting, and the possibility of breaking of the cutting blade itself is raised.

Accordingly, it is an object of the present invention to provide a cutting apparatus and a cutting method by which it is possible to prevent a workpiece and a cutting blade from being broken due to a lowering in cutting performance.

In accordance with an aspect of the present invention, there is provided a cutting apparatus for cutting a workpiece, including: holding means for holding the workpiece; cutting means including a cutting blade adapted to cut the workpiece held by the holding means, and a spindle adapted to rotate the cutting blade; cutting water supplying means for supplying cutting water to the cutting blade; and cleaning fluid jetting means for jetting to the cutting blade a cleaning fluid for removal of matter adhered to the cutting blade.

In the present invention, the cleaning fluid may be a mixed fluid of a gas and a liquid.

Besides, in the present invention, the cleaning fluid jetting means may jet the cleaning fluid to the cutting blade in a direction opposite to a rotating direction of the cutting blade.

In addition, in accordance with a mode of the present invention, there is provided a method of cutting a workpiece by the aforementioned cutting apparatus, the method including: a holding step of holding the workpiece by holding means; and a cutting step of cutting the workpiece held by the holding means by a cutting blade through rotating the cutting blade by a spindle while supplying cutting water to the cutting blade by cutting water supplying means, after the holding step is performed, wherein during when the cutting step is carried out, a cleaning fluid is jetted to the cutting blade to remove foreign matter adhered to the cutting blade.

In the cutting apparatus and the cutting method of the present invention, foreign matter (adhered matter) adhered to the cutting blade is removed by the cleaning fluid jetted from the cleaning fluid jetting means. This makes it possible to prevent cutting performance from being lowered due, for example, to adhesion of debris (cuttings) to the cutting blade. Therefore, according to the present invention, it is possible to prevent the workpiece and the cutting blade from being broken due to a lowering in cutting performance.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view showing schematically a configuration example of a cutting apparatus according to an embodiment of the present invention;

FIG. 2 is an exploded perspective view showing schematically a configuration example of a blade unit;

FIG. 3A is a front view showing schematically a peripheral structure of a cutting blade;

FIG. 3B is a plan view showing schematically the peripheral structure of the cutting blade;

FIG. 4A is a partially sectional side view showing schematically a holding step in a cutting method according to the embodiment of the present invention;

FIG. 4B is a front view showing schematically a cutting step in the cutting method according to the embodiment; and

FIG. 5 is a plan view showing schematically a peripheral structure of a cutting blade in a cutting apparatus according to a modification.

### DETAILED DESCRIPTION OF THE PREFERRED EMBODIMENT

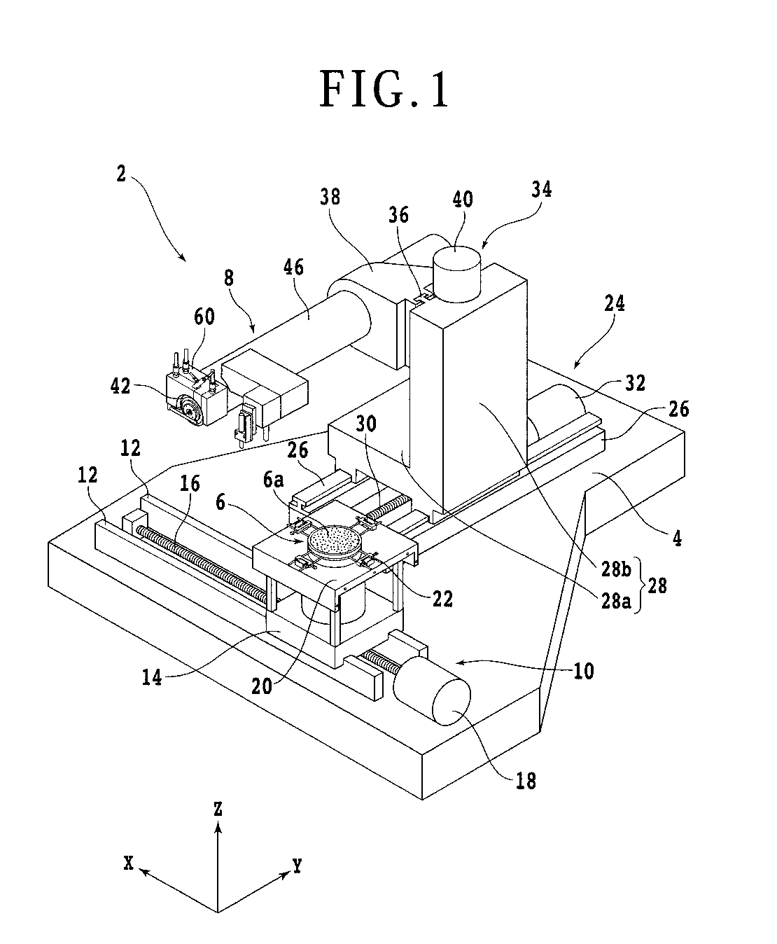

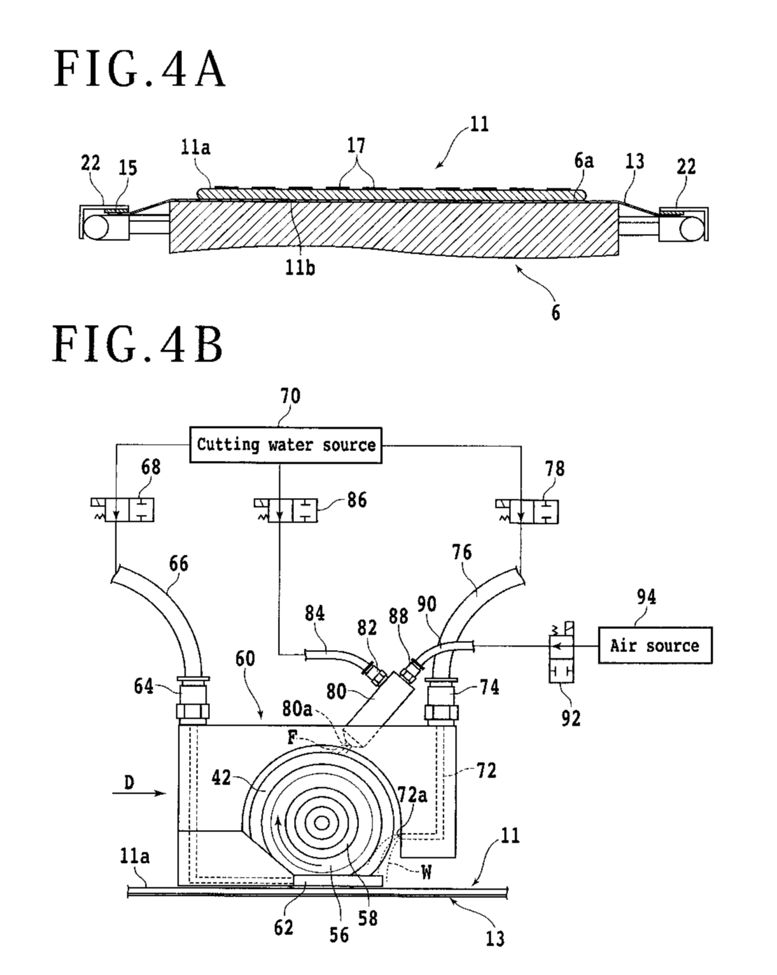

An embodiment of the present invention will be described below, referring to the attached drawings. FIG. 1 is a perspective view showing schematically a configuration example of a cutting apparatus according to an embodiment of the present invention. As shown in FIG. 1, the cutting apparatus 2 has a base 4 for supporting each component. On the upper side of the base 4 is provided a chuck table (holding means) 6 for holding a workpiece 11 (see FIG. 4A) such as a semiconductor wafer and a glass substrate. Over the chuck table 6 is disposed a blade unit (cutting means) 8 for cutting the workpiece 11.

Under the chuck table 6 is provided an X-axis moving mechanism (feeding mechanism) 10 for moving the chuck table 6 in a feeding direction (X-axis direction). The X-axis moving mechanism 10 includes a pair of X-axis guide rails 12 fixed to an upper surface of the base 4 and extending in parallel to the X-axis direction. On the X-axis guide rails 12, an X-axis moving table 14 is disposed slidably. On the back side (lower surface side) of the X-axis moving table 14, there is fixed a nut portion (not shown), which is in screw engagement with an X-axis ball screw 16 extending in parallel to the X-axis guide rails 12. The X-axis ball screw 16 is connected at its one end with an X-axis pulse motor 18. When the X-axis ball screw 16 is rotated by the X-axis pulse motor 18, the X-axis moving table 14 is moved along the X-axis guide rails 12 in the X-axis direction. On the front side (upper surface side) of the X-axis moving table 14, there is provided a support base 20.

In the center of the support base 20 is disposed the chuck table 6. In the periphery of the chuck table 6, there are provided four clamps 22 by which an annular frame 15 (see FIG. 4A) for holding the workpiece 11 is fixedly clamped from four sides. The chuck table 6 is connected with a rotating mechanism (not shown) provided under the support base 20, and is rotated about a rotational axis (vertical axis) parallel to a Z-axis. A surface of the chuck table 6 serves as a holding surface 6a on which the workpiece 11 is held by suction. A negative pressure of a vacuum source (not shown) acts on the holding surface 6a by way of a passage (not shown) formed in the inside of the chuck table 6, to generate a suction force for sucking the workpiece 11.

Adjacently to the X-axis moving mechanism 10, there is provided a Y-axis moving mechanism (indexing mechanism) 24 for moving the blade unit 8 in an indexing direction (Y-axis direction). The Y-axis moving mechanism 24 includes a pair of Y-axis guide rails 26 fixed to an upper surface of the base 4 and extending in parallel to the Y-axis direction. A Y-axis moving table 28 is slidably disposed on the Y-axis guide rails 26. The Y-axis moving table 28 includes a base portion 28a in contact with the Y-axis guide rails 26, and a wall portion 28b erected from the base portion 28a. On the back side (lower surface side) of the base portion 28a of the Y-axis moving table 28, there is fixed a nut portion (not shown), which is in screw engagement with a Y-axis ball screw 30 extending in parallel to the Y-axis guide rails 26. The Y-axis ball screw 30 is connected at its one end with a Y-axis pulse motor 32. When the Y-axis ball screw 30 is rotated by the Y-axis pulse motor 32, the Y-axis moving table 28 is moved along the Y-axis guide rails 26 in the Y-axis direction.

On the wall portion 28b of the Y-axis moving table 28, there is provided a Z-axis moving mechanism 34 for moving the blade unit 8 in the vertical direction (Z-axis direction). The Z-axis moving mechanism 34 includes a pair of Z-axis guide rails 36 fixed to a side surface of the wall portion 28b and extending in parallel to the Z-axis direction. On the Z-axis guide rails 36, a Z-axis moving table 38 is disposed slidably. On the back side (the wall portion 28b side) of the Z-axis moving table 38, there is fixed a nut portion (not shown), which is in screw engagement with a Z-axis ball screw (not shown) extending in parallel to the Z-axis guide rails 36. The Z-axis ball screw is connected at its one end with a Z-axis pulse motor 40. When the Z-axis ball screw is rotated by the Z-axis pulse motor 40, the Z-axis moving table 38 is moved along the Z-axis guide rails 36 in the Z-axis direction.

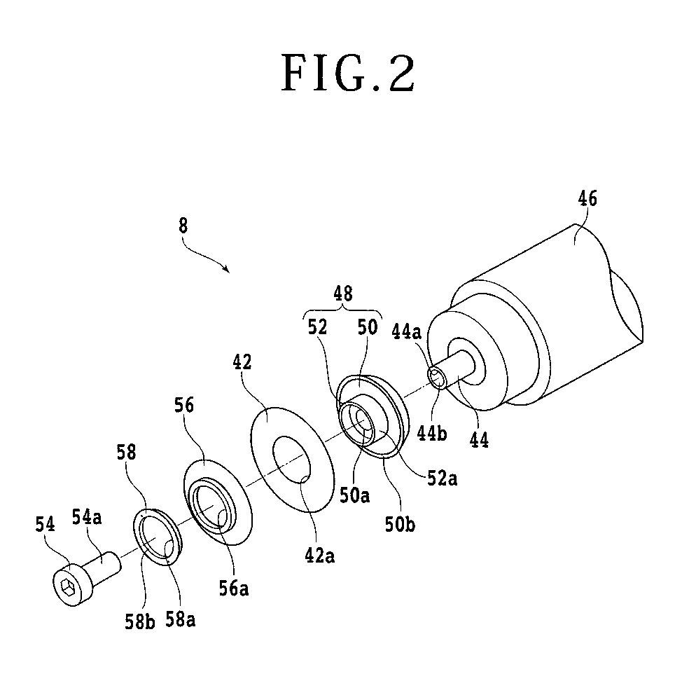

On the Z-axis moving table 38 is supported the blade unit 8 for cutting the workpiece 11. The blade unit 8 includes a cutting blade 42 having a circular annular shape. The cutting blade 42 is mounted to one end of a spindle 44 (see FIG. 2) which is rotated about a Y-axis. The other end of the spindle 44 is connected with a motor (not shown), which rotates the cutting blade 42 mounted to the spindle 44. The cutting blade 42 is rotated and made to cut into the workpiece 11, whereby the workpiece 11 is cut.

FIG. 2 is an exploded perspective view showing schematically a configuration example of the blade unit 8.

As aforementioned, the blade unit 8 includes the rotatable spindle 44, and the cutting blade 42 mounted to one end of the spindle 44. The spindle 44 is housed in a spindle housing 46 supported on the Z-axis moving table 38. A tip portion on the one end side of the spindle 44 protrudes from the spindle housing 46. A rear flange 48 to which the cutting blade 42 is mounted is attached to the tip portion of the spindle 44. The tip portion of the spindle 44 is formed with an opening 44a, and an inner wall surface 44b of the opening 44a is provided with a thread groove.

The rear flange 48 includes a flange portion 50 extended radially outward, and a boss portion 52 projected from a surface (front surface) of the flange portion 50. The flange portion 50 is formed in its center with an opening 50a penetrating the flange portion 50. In addition, the flange portion 50 is formed on the back surface (rear surface) side thereof with a fitting portion (not shown) into which the tip portion of the spindle 44 can be fitted. The fitting portion is provided in a position corresponding to the opening 50a. In the condition where the tip portion of the spindle 44 is fitted in the fitting portion formed in the flange portion 50, a rear flange fixing bolt 54 is fastened into the opening 50a and the opening 44a, whereby the rear flange 48 is fixed to the spindle 44. Note that an outer wall surface 54a of the rear flange fixing bolt 54 is provided with a thread ridge corresponding to the thread groove of the opening 44a. A surface on the outer peripheral side of the flange portion 50 constitutes an abutment surface 50b which is abutted on the back surface of the cutting blade 42. The abutment surface 50b is formed in a circular annular shape as viewed in the axial direction of the spindle 44.

The boss portion 52 is formed in a cylindrical shape, and its outer wall surface 52a is provided with a thread ridge. The cutting blade 42 is formed in the center thereof with an opening 42a through which the boss portion 52 is passed. The boss portion 52 is passed through the opening 42a, whereby the cutting blade 42 is mounted to the rear flange 48. In the condition where the cutting blade 42 is mounted to the rear flange 48, a front flange 56 having a circular annular shape is mounted to the front surface side of the cutting blade 42. The front flange 56 is formed with an opening 56a in the center thereof, and the boss portion 52 of the rear flange 48 is fitted in the opening 56a. Note that a back surface on the outer periphery side of the front flange 56 serves as an abutment surface (not shown) for abutment on the front surface of the cutting blade 42. This abutment surface is provided in a position corresponding to the abutment surface 50b of the rear flange 48.

After the front flange 56 is mounted, a front flange fixing nut 58 having a circular annular shape is fastened onto a tip portion of the boss portion 52. As a result, the front flange 56 is pushed toward the rear flange 48, and the cutting blade 42 is clamped between the flanges constituted of the rear flange 48 and the front flange 56. Specifically, the front surface of the cutting blade 42 is abutted on the abutment surface of the front flange 56, and the back surface of the cutting blade 42 is abutted on the abutment surface 50b of the rear flange 48, whereby the cutting blade 42 is held in a predetermined position. Note that the front flange fixing nut 58 is provided with an opening 58a, and an inner wall surface 58b of the opening 58a is formed with a thread groove.

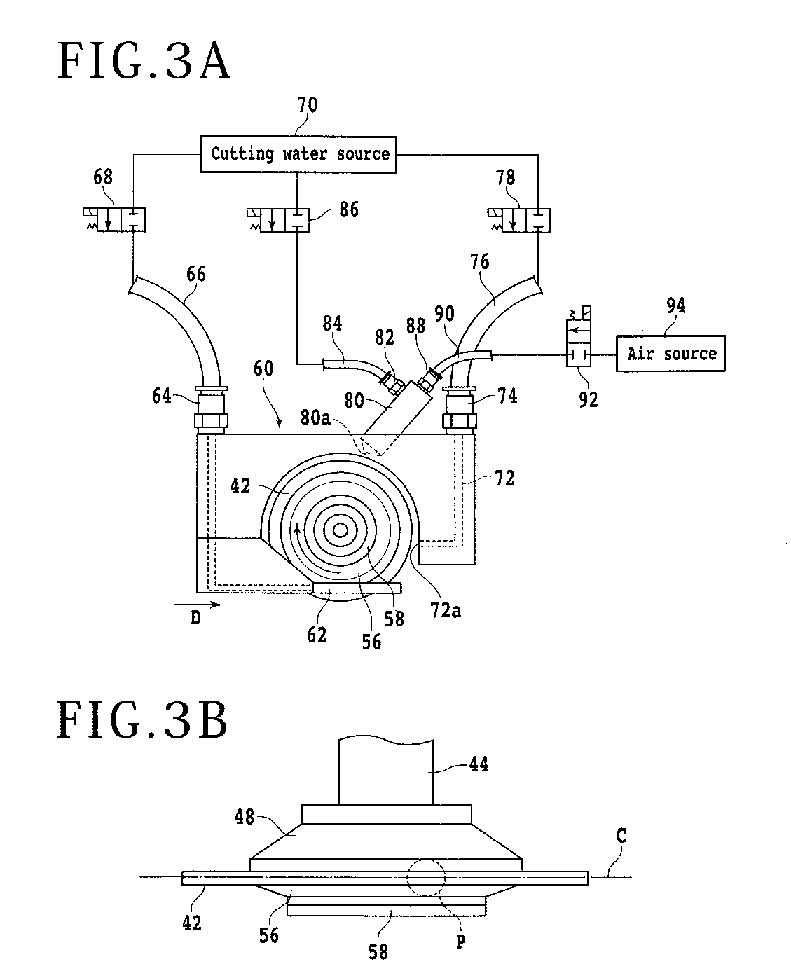

Onto the blade unit 8 configured as above is mounted a blade cover 60 for housing the cutting blade 42 (FIG. 1). The outer periphery of the cutting blade 42 is covered, except for a lower portion thereof, by the blade cover 60. FIG. 3A is a front view showing schematically a peripheral structure of the cutting blade 42. FIG. 3B is a plan view showing schematically the peripheral structure of the cutting blade 42. Note that in FIGS. 3A and 3B, part of the configuration is omitted or is drawn in a simplified form.

As shown in FIG. 3A, on one side of the blade cover (on the rear side with respect to the forward moving direction D of the cutting blade 42), there are fixed a pair of roughly L-shaped blade cooler nozzles (cutting water supplying means) 62 disposed respectively on opposite sides of a lower portion of the cutting blade 42. The blade cooler nozzles 62 are connected to a cutting water source 70 through a connection portion 64 provided at an upper portion of the blade cover 60, a piping 66 connected to the connection portion 64, a valve 68 inside the piping 66, and the like. The blade cooler nozzles 62 are each formed on the tip side thereof with a plurality of slits (not shown) which face the cutting blade 42. Cutting water is jetted through the plurality of slits, thereby to cool the vicinity of a processing point of the cutting blade 42.

On the other side of the blade cover 60 (on the front side with respect to the forward moving direction D of the cutting blade 42), there is provided a shower nozzle (cutting water supplying means) 72 for supplying cutting water to the cutting blade 42. The shower nozzle 72 is connected with the cutting water source 70 through a connection portion 74 provided at an upper portion of the blade cover 60, a piping 76 connected to the connection portion 74, a valve 78 inside the piping 76, and the like. A tip portion of the shower nozzle 70 serves as a supply port 72a for supplying the cutting water to the cutting blade 42. The cutting water is thus supplied through the shower nozzle 72 and the supply port 72a, whereby the cutting blade 42 is cooled and the workpiece 11 can be cut favorably.

In addition, at a central upper portion of the blade cover 60, there is provided a cleaning fluid supply nozzle (cleaning fluid supplying means) 80 for supplying a cleaning fluid for cleaning the cutting blade 42. The cleaning fluid supply nozzle 80 is formed on the lower end side thereof with a cleaning fluid jet port 80a for jetting the cleaning fluid toward the cutting blade 42. The cleaning fluid supply nozzle 80 is connected with the cutting water source 70 through a first connection portion 82 provided on the upper end side of the cleaning fluid supply nozzle 80, a piping 84 connected with the first connection portion 82, a valve 86 inside the piping 84, and the like. Besides, the cleaning fluid supply nozzle 80 is connected with an air source 94 through a second connection portion 88 provided on the upper end side of the cleaning fluid supply nozzle 80, a piping 90 connected with the second connection portion 88, a valve 92 inside the piping 90, and the like. The cutting water supplied from the cutting water source 70 and air supplied from the air source 94 are mixed with each other in the cleaning fluid supply nozzle 80, to be jetted as a cleaning fluid from the cleaning fluid jet port 80a. In other words, the cleaning fluid used in this embodiment is a mixed fluid (two fluids) formed by mixing air (gas) and water (liquid) with each other.

The cleaning fluid supply nozzle 80 is so disposed that the cleaning fluid jet port 80a is directed obliquely toward a rear lower side. In addition, as shown in FIG. 3B, the cleaning fluid supply nozzle 80 is so disposed that a jet position P of the cleaning fluid coincides with a center position C in the thickness direction of the cutting blade 42. Since the cutting blade 42 is rotated clockwise in the front view shown in FIG. 3A, the cleaning fluid is jetted in a direction against the rotation of the cutting blade 42. In other words, the jetting direction of the cleaning fluid is roughly opposite to the rotating direction of the cutting blade 42. Thus, the cleaning fluid supply nozzle 80 is so configured as to jet the cleaning fluid toward the cutting blade 42 in the direction against the rotation of the cutting blade 42, whereby foreign matter (adhered matter) adhered to the cutting blade 42 can be removed powerfully. This makes it possible to prevent cutting performance from being lowered due, for example, to adhesion of debris (cuttings) to the cutting blade 42. Therefore, it is possible to prevent the workpiece 11 and the cutting blade 42 from being broken due to a lowering in cutting performance.

An example of a cutting method by use of the cutting apparatus 2 according to this embodiment will now be described below. FIG. 4A is a partially sectional side view showing schematically a holding step in the cutting method according to this embodiment. FIG. 4B is a front view illustrating schematically a cutting step in the cutting method.

In the cutting method according to this embodiment, first, a holding step is performed in which the workpiece 11 is held on the chuck table 6. As shown in FIG. 4A, the workpiece 11 is, for example, a disk-shaped semiconductor wafer, which is supported on the annular frame 15 through a dicing tape 13 attached to a back side 11b of the workpiece 11. A front side 11a of the workpiece 11 is sectioned into a plurality of regions by streets (predetermined processing lines) arranged in a grid pattern, and a device 17 such as an IC is provided in each of the regions. In the holding step, first, the workpiece 11 is placed on the chuck table 6, with its dicing tape 13 side set in contact with the holding surface 6a of the chuck table 6, and a negative pressure of a vacuum source is applied. By this holding step, the workpiece 11 is suction held onto the chuck table 6 through the dicing tape 13 therebetween.

After the holding step is finished, a cutting step is conducted in which the workpiece 11 held on the chuck table 6 is cut by the cutting blade 42. In the cutting step, first, the chuck table 6 and the cutting blade 42 are brought into a relative movement by the X-axis moving mechanism 10 and the Y-axis moving mechanism 24 so that the cutting blade 42 is positioned into a position over the street on the workpiece 11. Next, the cutting blade 42 rotated by the motor and the spindle 44 is made to cut into the workpiece 11, and the chuck table 6 and the cutting blade 42 are brought into a relative movement (feeding) in the X-axis direction by the X-axis moving mechanism 10. The cutting-in depth of the cutting blade 42 is so set, for example, that a leading end portion of the cutting blade 42 substantially reaches the dicing tape 13. In addition, as shown in FIG. 4B, the cutting water W is preliminarily supplied to the cutting blade 42 by use of the blade cooler nozzles 62 and the shower nozzle 72. By the cutting step as above, the workpiece 11 is cut along the streets.

Meanwhile, when the cutting blade 42 is made to cut into the dicing tape 13, as in the cutting step in this embodiment, debris (cuttings) generated at the dicing tape 13 are likely to stick to the cutting blade 42, thereby clogging the cutting blade 42. As a result, the cutting performance of the cutting blade 42 is lowered. A similar phenomenon is liable to occur also in the case of cutting a workpiece 11 formed of a highly viscous metal or resin or the like or a workpiece 11 in which a highly viscous material is arranged on the streets. If the cutting of the workpiece 11 by the cutting blade 42 thus lowered in cutting performance is continued, the risk of breakage of the workpiece 11 or the cutting blade 42 is increased. Taking this into account, in the cutting method according to this embodiment, a cleaning fluid F is jetted from the cleaning fluid supply nozzle 80 toward the cutting blade 42 during the cutting step, to remove foreign matter (adhered matter) such as debris (cuttings) adhered to the cutting blade 42.

In this embodiment, for example, the flow rate of the cutting water supplied from the cutting water source 70 to the cleaning fluid supply nozzle 80 is set to be 0.2 L/min to 0.3 L/min, and the pressure of air supplied from the air source 94 to the cleaning fluid supply nozzle 80 is set to be 0.4 MPa. The cleaning fluid F formed by mixing the cutting water and the air under such a flow rate and a pressure is jetted toward the cutting blade 42, whereby the foreign matter (adhered matter) can be removed powerfully.

The cleaning fluid F may be jetted in an arbitrary manner. For instance, the cleaning fluid F may be constantly jetted or may be jetted at predetermined intervals, during when the cutting step is conducted. By jetting the cleaning fluid F to the cutting blade 42 and thereby removing the foreign matter such as debris (cuttings) in this way, the once lowered cutting performance of the cutting blade 42 can be recovered. As a result, the workpiece 11 and the cutting blade 42 can be prevented from being broken due to a lowering in cutting performance.

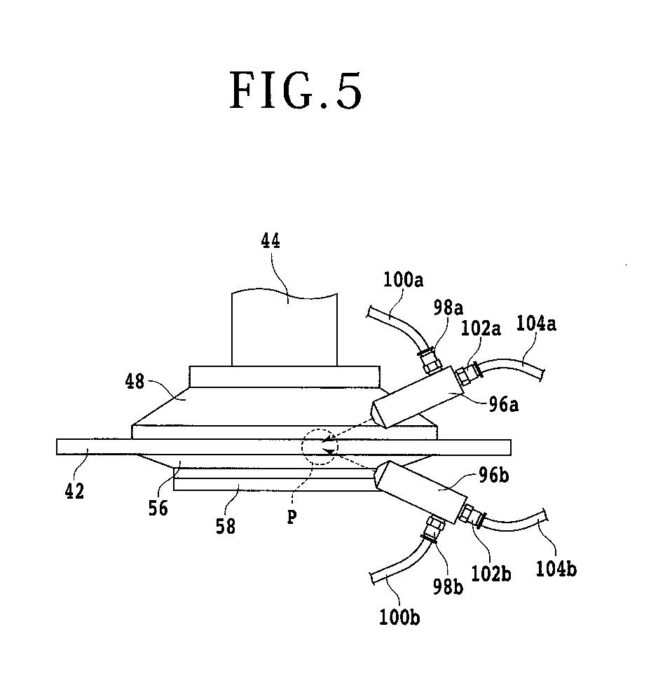

It is to be noted that the present invention is not limited to the embodiment described above, and can be carried out with various modifications. For instance, while the cutting apparatus 2 having one cleaning fluid supply nozzle 80 has been described in the above embodiment, the cutting apparatus may have two or more cleaning fluid supply nozzles. FIG. 5 is a plan view showing schematically a peripheral structure of a cutting blade in a cutting apparatus according to a modification. The cutting apparatus depicted in FIG. 5 includes two cleaning fluid supply nozzles (cleaning fluid supplying means) 96a and 96b for supplying a cleaning fluid F toward a jet position P. The configuration of each of the cleaning fluid supply nozzles 96a and 96b is the same as that of the cleaning fluid supply nozzle 80 described above. Specifically, the cleaning fluid supply nozzles 96a and 96b are connected with a cutting water source (not shown) by way of first connection portions 98a and 98b provided at the cleaning fluid supply nozzles 96a and 96b, pipes 100a and 100b connected to the first connection portions 98a and 98b, valves (not shown) inside the pipes 100a and 100b, and the like. In addition, the cleaning fluid supply nozzles 96a and 96b are connected with an air source by way of second connection portions 102a and 102b provided at the cleaning fluid supply nozzles 96a and 96b, pipes 104a and 104b connected to the second connection portions 102a and 102b, valves (not shown) inside the pipes 104a and 104b, and the like. By providing the cutting apparatus with the two cleaning fluid supply nozzles 96a and 96b in this manner, the foreign matter (adhered matter) adhered to the cutting blade 42 can be removed more powerfully. Note that the cutting apparatus may be provided with three or more cleaning fluid supply nozzles.

In addition, while the cleaning fluid supply nozzle 80 is disposed at a central upper portion of the blade cover 60 in the aforementioned embodiment, the position where the cleaning fluid supply nozzle 80 is arranged is not particularly restricted. For example, a configuration may be adopted in which the cleaning fluid supply nozzle 80 is arranged on one side (the rear side with respect to the forward moving direction D of the cutting blade 42) of the blade cover 60, and the cleaning fluid F is jetted toward the cutting blade 42 exposed at a lower portion of the blade cover 60.

Besides, while the mixed fluid (two fluids) formed by mixing a gas and a liquid with each other is used as the cleaning fluid F in the above-described embodiment, other fluid may also be used as the cleaning fluid F. For instance, a liquid to which ultrasound is applied (representatively, pure water (ultrasonically vibrated water)) may be used as the cleaning fluid F.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting apparatus for cutting a workpiece, comprising:
holding means for holding the workpiece;
cutting means including a cutting blade adapted to cut the workpiece held by the holding means, and a spindle adapted to rotate the cutting blade;
cutting water supplying means for supplying cutting water to the cutting blade; and
cleaning fluid jetting means for jetting to the cutting blade a cleaning fluid for removal of matter adhered to the cutting blade.

2. The cutting apparatus according to claim 1, wherein the cleaning fluid includes a mixed fluid of a gas and a liquid.

3. The cutting apparatus according to claim 1, wherein the cleaning fluid jetting means jets the cleaning fluid to the cutting blade in a direction opposite to a rotating direction of the cutting blade.

4. A method of cutting a workpiece by the cutting apparatus according to claim 1, the method comprising:
a holding step of holding the workpiece by holding means; and
a cutting step of cutting the workpiece held by the holding means by a cutting blade through rotating the cutting blade by a spindle while supplying cutting water to the cutting blade by cutting water supplying means, after the holding step is performed,
wherein during when the cutting step is carried out, a cleaning fluid is jetted to the cutting blade to remove foreign matter adhered to the cutting blade.
